(19) United States
(12) Patent Application Publication
(10) Pub. No.: US 2025/0142925 A1
(43) Pub. Date: May 1, 2025

(54) ADAPTIVE EDGE TERMINATION BY DESIGN FOR EFFICIENT AND RUGGED HIGH VOLTAGE SILICON CARBIDE POWER DEVICE

(71) Applicant: VISHAY SILICONIX LLC, San Jose, CA (US)

(72) Inventors: Ayman SHIBIB, San Jose, CA (US); Jinman YANG, Santa Clara, CA (US); Misbah AZAM, San Jose, CA (US)

(73) Assignee: VISHAY SILICONIX LLC, San Jose, CA (US)

(21) Appl. No.: 18/837,074

(22) PCT Filed: Feb. 10, 2022
(86) PCT No.: PCT/US2022/015910

§ 371 Date: Aug. 8, 2024

(51) Int. Cl. H10D 64/00; G06F 30/31; H01L 23/528; H10D 64/66; H10D 89/10

(52) U.S. Cl. CPC H10D 64/112; G06F 30/31; H01L 23/5283; H10D 89/10; H10D 64/661

(57) ABSTRACT

A semiconductor device is provided including two or more termination units. Each termination unit can include a via channel, a connection via, floating field rings, a metal plate, and a floating field plate. The floating field rings may include a first floating field ring having a first width and a second floating field ring having a second width. The first width may be different than the second width. The metal plate is coupled to the first floating field ring through the via channel. The floating field plate is coupled to the metal plate through the connection via. The termination units provide an adaptive electric field distribution configured to dissipate a voltage passing from a drain of the semiconductor device to a source of the semiconductor device.

### FIELD OF INVENTION

The present disclosure relates to semiconductor devices, and is more particularly related to high voltage semiconductor devices having certain parameters configured or adapted for increased performance, ruggedness, and reliability.

### BACKGROUND

Generally, in conventional high voltage or power technologies, semiconductors provide edge termination and potential field distribution by implementing the highest possible termination voltage above a breakdown voltage. These edge termination designs mostly focus on a region inside the semiconductor with a few cases considering regions above the semiconductor surface.

In practice, conventional technologies require that edge termination elements of semiconductors have fixed voltages to implement the edge termination and the potential field distribution.

For example, an edge termination element, such as a floating field plate, is merely placed within an insulation layer, above the semiconductor surface, with no connections to other edge termination elements, such as a metal plate, and to a floating field ring within the semiconductor layers. In this way, the edge termination element is capacitively coupled with the other edge termination elements. The capacitive coupling is strictly dependent on material, permittivity, conductance, etc. Therefore, because these edge termination elements of the insulation layer are not connected, the fixed voltages depend strictly on material properties for the potential field distribution (i.e., a leakage between the insulation layer and the edge termination elements).

As another example, some edge termination conventional technologies focus strictly on regions below the semiconductor surface, such as floating field rings, junction termination extension, Reduced Electric Field (RESURF), or a combination thereof. Yet, a process control of epitaxial layer concentrations and tight control of RESURF layer implants have inherent manufacturability limitations, such as in yield and reliability terms.

The potential field distribution provided by the insulation layer is not controlled by designing locations and sizes of the edge termination elements. That is, regardless of how the locations and sizes of the elements are determined, the capacitive coupling governs the potential field distribution. Note, also, that being strictly dependent on material properties to affect a capacitive coupling is a serious limitation that has prevented a widespread adaption by conventional technologies of using the floating field plates as edge termination.

What is needed is new and/or improved methods and systems for managing potential field distributions within the semiconductor edge termination and above the semiconductor surface by enabling direct control of how the edge termination elements can provide the potential field distribution. Further, such new and/or improved methods and systems preferably include a more comprehensive approach to high voltage edge termination designs to address all aspects of termination inside and at the surface of the semiconductor edge termination region.

### SUMMARY

According to one or more embodiments, a semiconductor device including two or more termination units is provided herein. Each termination unit can include a via channel, a connection via, floating field rings, a metal plate, and a floating field plate. The floating field ring include a first floating field ring having a first width and a second floating field ring having a second width. In one or more embodiments, the first width can be different than the second width. The metal plate is coupled to the first floating field ring through the via channel. The floating field plate is coupled to the metal plate through the connection via. The termination units provide an electric field distribution configured to dissipate a voltage passing from a drain of the semiconductor device to a source of the semiconductor device.

Also, according to one or more embodiments, a termination unit of semiconductor device is provided herein. The termination unit includes a via channel, a connection via, a plurality of floating field rings, a metal plate coupled to the first floating field ring through the via channel, and a floating field plate coupled to the metal plate through the connection via. A drain side surface of the metal plate extends beyond or is outside of a drain side surface of an epitaxial layer of the semiconductor device. A drain side length of the metal plate is equal to or greater than a junction depth of the epitaxial layer.

Further, according to one or more embodiments, a method of making, fabricating, modifying and/or determining the design of a semiconductor device is provided herein. The method may be implemented by software stored on a memory and executed by a processor. The method may include determining a breakdown voltage design target based on a desired or determined breakdown voltage for a semiconductor design. The method may include generating a structure for the semiconductor design that includes at least two termination units. The structure may be generated according to or otherwise considering the breakdown voltage design target by utilizing or considering an incremental voltage drop per termination unit, a number of termination units, and/or the composition, layout, or other parameters comprising the elements or design of the elements provided per termination unit. The method may also include evaluating whether the structure includes a uniform distribution or an energy below a critical field to determine a final termination layout design for a semiconductor device. Additional aspects and embodiments are disclosed herein.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1 depicts a diagram of an adaptive edge termination semiconductor device according to one or more embodiments.

FIG. 2 depicts a diagram of a termination unit according to one or more embodiments.

FIG. 3 depicts a block diagram of a method of producing an adaptive edge termination semiconductor device according to one or more embodiments.

FIG. 4 a diagram of a diagram of an electrical termination layer according one or more embodiments.

FIG. 5 depicts a diagram of a structure of an adaptive edge termination semiconductor device according to one or more embodiments.

FIG. 6 a diagram of a gradual distribution of an electric field of an adaptive edge termination semiconductor device according one or more embodiments.

FIG. 7 a diagram of an adaptive edge termination semiconductor device according to one or more embodiments.

### DETAILED DESCRIPTION

Reference will now be made in detail to various embodiments of the invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

Certain terminology is used in the following description for convenience only and is not limiting. The words “right,” “left,” “top,” and “bottom” designate directions in the drawings to which reference is made. The words “a” and “one,” as used in the claims and in the corresponding portions of the specification, are defined as including one or more of the referenced item unless specifically stated otherwise. This terminology includes the words above specifically mentioned, derivatives thereof, and words of similar import. The phrase “at least one” followed by a list of two or more items, such as “A, B, or C,” means any individual one of A, B or C as well as any combination thereof. It may be noted that some figures are shown with partial transparency for the purpose of explanation, illustration and demonstration purposes only, and is not intended to indicate that an element itself would be transparent in its final manufactured form.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region, substrate, lead, clip, pad, or contact is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. It will be understood that these terms are intended to encompass different orientations of the element in addition to any orientation depicted in the figures.

Relative terms such as “below” or “above” or “upper” or “lower” or “horizontal” or “vertical” may be used herein to describe a relationship of one element, layer or region to another element, layer, region. It will be understood that these terms are intended to encompass different orientations of the device in addition to the orientation depicted in the figures.

The figures are not drawn to scale, and only portions of the structures, as well as the various layers that form those structures, may be shown in the figures. The figures, in general, illustrate symbolic and simplified structures to convey understanding of the invention, and are not intended to reproduce physical structures in detail. Furthermore, fabrication processes and operations may be performed along with the processes and operations discussed herein; that is, there may be a number of process operations before, in between and/or after the operations shown and described herein. Further, embodiments in accordance with the present invention can be implemented in conjunction with these other (perhaps conventional) processes and operations without significantly perturbing them. Generally, embodiments in accordance with the present invention may replace and/or supplement portions of a conventional process without significantly affecting peripheral processes and operations.

The term “MOSFET” is generally understood to be synonymous with the term insulated-gate field-effect transistor (IGFET), as many modern MOSFETs comprise a non-metal gate and/or a non-oxide gate insulator. As used herein, the term “MOSFET” does not necessarily imply or require FETs that include metal gates and/or oxide gate insulators. Rather, the term “MOSFET” includes devices commonly known as or referred to as MOSFETs.

The term “substantially” in the description and claims of the present application is used to refer to design intent, rather than a physical result. The semiconductor arts have deployed an ability to measure numerous aspects of a semiconductor to a high degree of accuracy. Accordingly, when measured to available precision, in general, no physical aspect of a semiconductor is precisely as designed. Further, measurement technology may readily identify differences in structures that are intended to be identical. Accordingly, terms such as “substantially equal” should be interpreted as designed to be equal, subject to manufacturing variation and measurement precision.

The present disclosure relates to semiconductors, and is more particularly related to adaptive edge termination by design for efficient and rugged silicon carbide power device. The efficient and rugged silicon carbide power device can be referred to herein as an adaptive edge termination semiconductor device or package (which may also be referred to as a “device” or “package” or “component”).

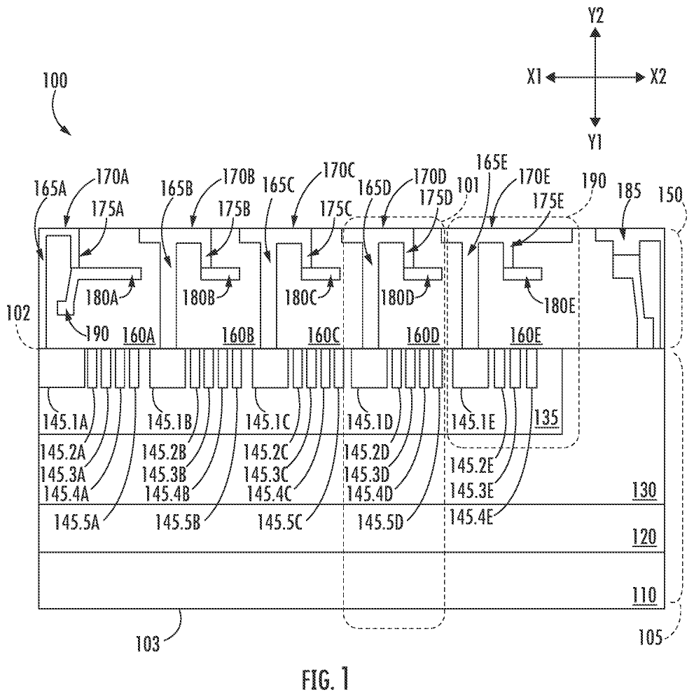

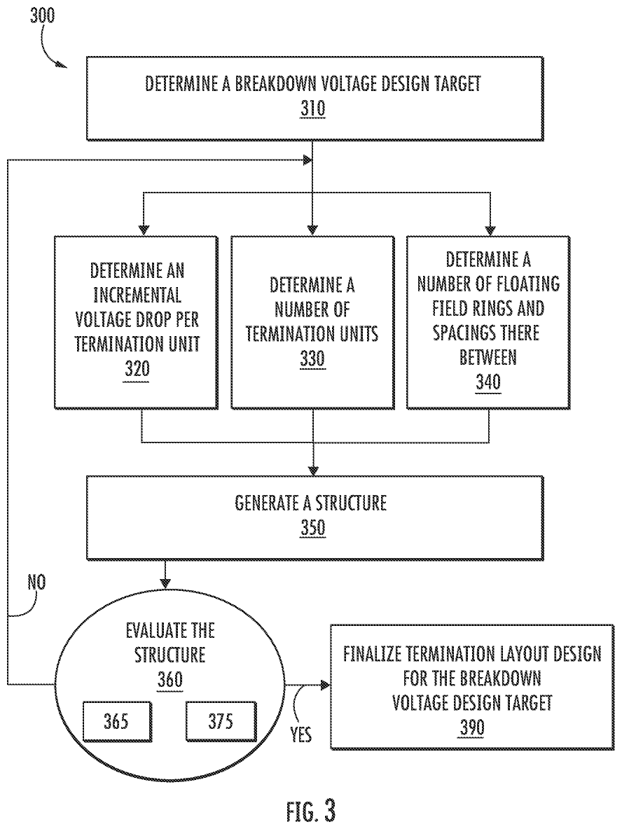

According to one or more embodiments, a semiconductor device (e.g., a semiconductor device 100 of FIG. 1) and a design method (e.g., a method 300 of FIG. 3) for making such a semiconductor device 100 comprise an adaptive edge termination configured to provide control or adaptation as to how one or more termination elements of various layers of the semiconductor device manage potential electric field distributions (which may be referred to as “electric field distributions”). The semiconductor device may comprise a MOSFET. The semiconductor device and the design method accomplish such control or adaptation through the design and application of one or more termination units that implement an adaptive voltage drop by coupling and locating termination elements, as well as determining certain parameters of the components of such termination elements. By way of example, while conventional technologies utilize a fixed voltage edge termination element placed within the insulation layer with no connections to other edge termination elements, each termination unit groups field plates with two or more floating field rings to distribute a voltage adapted to parameters, such as physical characteristics of the components. Such parameters can include, but are not limited to, location, orientation, dimension size, spacing, the materials used for such components, etc.

One or more technical effects, advantages, and benefits of the semiconductor device and design method include a design approach focus that increases performance, ruggedness, stability, and long term reliability of the semiconductor device. In contrast to conventional technologies, the semiconductor device and the design method herein are configured to remove or diminish any fixed voltages, control by design the electrical field distribution, form physical charge barriers, and address manufacturing variations and dielectric film charges that result in unstable termination break down voltages.

FIG. 1 depicts a diagram of the semiconductor device 100 according to one or more embodiments. Generally, parameters of components of the semiconductor device 100 may include, but are not limited to, with respect to various elements or components, materials, structure, location, orientation, spacing, dimensions, (e.g., width, height, depth, dimension, area, volume) and shapes. Such parameters are controlled and/or determined by the design method, preferably the method or methods as described herein.

The diagram of FIG. 1 depicts the semiconductor device 100 comprising two or more termination units (with a termination unit 101 being an example of such units), a source 102, and a drain 103 of the semiconductor device 100. As shown in FIG. 1, five (5) example termination units A-E are depicted. The edge termination elements of the semiconductor device are identified/grouped according to A-E to correspond to the termination units A-E. The diagram of FIG. 1 is oriented according to an X1-X2 axis (e.g., generally horizontal as oriented in the Figures, with the axis having a direction between left and right as in FIG. 1) and a Y1-Y2 axis (e.g., generally vertically as oriented in the Figures, with the axis having a direction between down and up as in FIG. 1). The X1 direction is opposite the X2 direction, and the Y1 direction is opposite the Y2 direction. Other orientations can be made in accordance with the X1-X2 and Y1-Y2 axes, which may be tilted or angled. Reference to a left side or left facing surface of a component described may be referred to as an X1 side or an X1 surface of the component, while reference to a right side or right facing surface of a component described may be referred to as an X2 side or an X2 surface of the component. Similarly, reference to a lower or bottom side or a downwardly facing surface of a component described may be referred to as a Y1 side or a Y1 surface, while reference to a top or upper side or upwardly facing surface of a component described may be referred to as a Y2 side or a Y2 surface.

The semiconductor device 100 can include one or more doping configurations. Examples of doping configurations are further discussed herein, without limitation to the semiconductor device 100. Further, as used herein, the letter “n” refers to an n-type dopant and the letter “p” refers to a p-type dopant. A plus sign “+” or a minus sign “−” is used to represent, respectively, a relatively higher or relatively lower concentration of such dopant(s). However, such use does not limit the absolute doping range or other aspects of these regions. For example, a doping area described as n+ or n− may also be described as an n-type doping region.

The diagram shown in FIG. 1 depicts a first region 105. The first region 105 may comprise one or more layers. The first region 105 preferably comprises a substrate layer 110, a buffer layer 120, an epitaxial layer 130, and an electrical termination layer 135 with one or more floating field rings 145 therein. That is, the first region 105 can include the one or more edge termination elements, such as the one or more floating field rings 145 embedded/implanted in the electrical termination layer 135 (e.g., an implanted layer).

The substrate layer 110 may be formed as or otherwise comprise a portion of the first region 105 used for fabrication of at least the buffer layer 120 and the epitaxial layer 130. The buffer layer 120 and the epitaxial layer 130 may be formed/grown on the substrate layer 110 to match the crystallinity thereof. According to one or more embodiments, because the doping of the epitaxial layer 130 can vary per foundry, the buffer layer 120 having a higher doping concentration than the epitaxial layer 130 (e.g., such as 10% more) as described herein.

The electrical termination layer 135 may be formed as or otherwise comprise a depletion layer in which one or more edge termination elements are embedded. The electrical termination layer 135 acts as a barrier or transition area between the epitaxial layer 130 and the second region 150, so that the floating field rings 145 are not in direct contact with or otherwise embedded in the epitaxial layer 130 and one or more p-n junctions of the semiconductor device 100 are shifted downward to where the electrical termination layer 135 and epitaxial layer 130 meet. The floating field rings 145 are described herein in greater detail.

The diagram of FIG. 1 also depicts a second region 150 shown above, i.e., adjacent an upper or X2 side of, the first region 105. The second region 150 can include one or more layers. The second region 150 can be a single material, such as a single insulating/dielectric material. According to one or more embodiments, the second region 150 preferably comprises a dielectric film 160. The dielectric film 160 is shown as with A-E designation to indicate portions thereof that match with each termination unit A-E.

According to one or more embodiments, the dielectric film 160 may be formed having or otherwise comprise one or more connections (e.g., one or more channel vias 165 and one or more connection vias 175) and edge termination elements (e.g., one or more metal plates 170 and one or more floating field plates 180) embedded therein. The one or more connections and edge termination elements can include metal and/or polysilicon. For instance, the floating field plates 180, described in greater detail herein, can include polysilicon.

According to one or more embodiments, a specification of the termination unit can include at least one floating field rings 145 (e.g., generally four or more), one channel via 165, one metal plate 170, one connection via 175, and one floating field plate 180. In this regard, a combination of the channel via 165, the metal plate 170, and the connection via 175 within each termination unit A-E can comprise metal that is continuous from the corresponding floating field ring 145 to the corresponding floating field plate 180 (i.e., not separate sections). According to one or more embodiments, the metal plate 170 can be one section or piece, and the channel via 165 and the connection via 175 can be a same section or layer but different than the metal plate 170.

Further, each of the two or more termination units (with the termination unit 101 being an example of such units) can further comprise one or more floating field rings 145. As shown in FIG. 1, for example, the five (5) example termination units A-E comprise floating field rings 145 as designated by the additional alphanumerical annotations. In this regard, a left most (i.e., the X1 side of the semiconductor device 100) termination unit A includes five floating field rings 145.1A-145.5A, as well as the channel via 165A, the metal plate 175A, the connection via 175A, and the floating field plate 180A. A second left most termination unit B includes five floating field rings 145.1B-145.5B, as well as the channel via 165B, the metal plate 175B, the connection via 175B, and the floating field plate 180B. A middle termination unit C includes five floating field rings 145.1C-145.5C, as well as the channel via 165C, the metal plate 175C, the connection via 175C, and the floating field plate 180C. A second right most termination unit D (i.e., shown as example termination unit 101) includes five floating field rings 145.1D-145.5D, as well as the channel via 165D, the metal plate 175D, the connection via 175D, and the floating field plate 180D. A right most (i.e., the X2 side of the semiconductor device 100) termination unit E includes four floating field rings 145.1E-145.4E, as well as the channel via 165E, the metal plate 175E, the connection via 175E, and the floating field plate 180E.

Each floating field ring 145 is dynamically configured to acquire and/or adapt a voltage based on parameters. The floating field rings 145 comprise metal and/or polysilicon according to one or more parameters. According to one or more embodiments, a structure, size, width, dimension, area, etc. of each floating field ring 145, a location of each floating field ring 145, and a spacing between each of the floating field ring 145 enable a corresponding termination unit to dynamically adapt to a potential/voltage applied to the semiconductor device 100. According to one or more embodiments, the floating field rings 145 can comprise a p-type region formed at a same time and by a same process as a body implanted and diffused region (e.g., the electrical termination layer 135) of the semiconductor device 100 (e.g., the MOSFET).

Additionally, the diagram of FIG. 1 depicts a high voltage side metal plate 185 and a gate 190. The high voltage side metal plate 185 can distribute any initial voltage at a drain side of the semiconductor device 100. Further, the gate 190 is connecting to the core of the semiconductor device and can be of the same material as the floating field plate 180A.

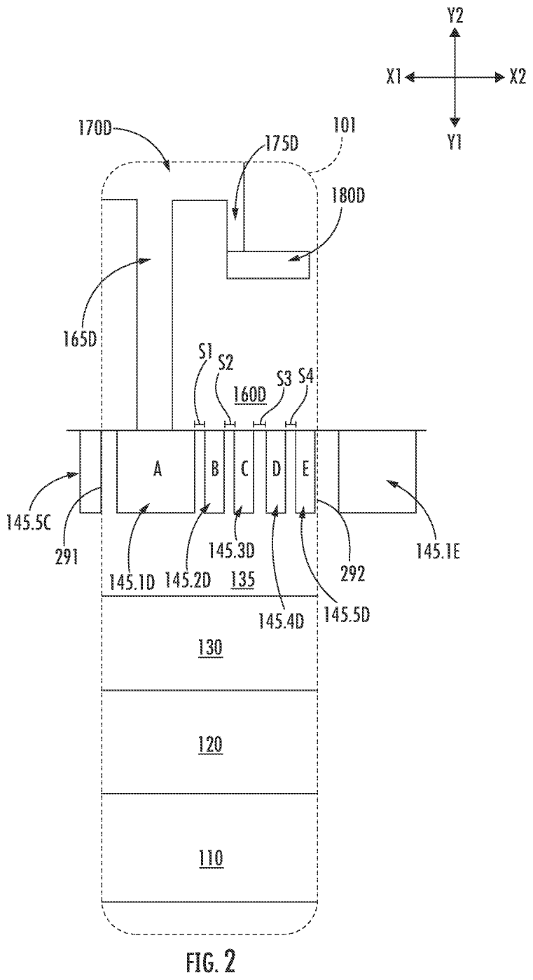

In the orientation of the semiconductor device 100 as shown in FIG. 1, the first region 105 has a bottom or Y1 surface and a top or Y2 surface. The second region 150 also has a bottom or Y1 surface and a top or Y2 surface. The top surface (i.e., a Y2 surface) of the first region 105 is adjacent the bottom surface (i.e., a Y1 surface) of the second region 150. In this regard, a bottom side (i.e., a Y1 side) of the dielectric film 160 is in contact with the first region 105 or a top side (i.e., a Y2 side) the epitaxial layer 130. Further, the electrical termination layer 135 may extend in the X1-X2 direction from a left or X1 side to a right or X2 side. The left or X1 side of the electrical termination layer 135 can be aligned with a left or X1 surface of the epitaxial layer 130, while the right or X2 side or the electrical termination layer 135 can be positioned within the epitaxial layer 130. In the Y1-Y2 direction, the electrical termination layer 135 may extend from the bottom or Y1 surface of the dielectric film 160 to an area or depth within the epitaxial layer 130, below the lower or Y1 surfaces of the floating field rings 145. According to one or more embodiments, the termination unit 101 may extend from the upper or Y2 surface of the second region 150 to the lower or Y1 surface of the first region (i.e., the substrate layer 110), which is further described herein with respect to FIG. 2.

Generally, a breakdown voltage (BV) is an applied voltage at which significant impact ionization occurs and some current starts to flow through any device (e.g., the semiconductor device 100). A termination region at the edge of a typical high voltage device is most susceptible to instability of the BV because the voltage varies in the termination region from a source voltage (usually at ground potential) to a drain voltage at the edge of the typical high voltage device (which is the full drain potential). Without proper management, this voltage can creep up to a surface of the typical high voltage device and result in a field distribution issue. The typical high voltage device with conventional technologies can manage a BV of approximately 300 volts. In contrast, one or more embodiments of the semiconductor device 100 herein can manage a BV of 650 volts or higher. Examples of “high” BV include, but are not limited to, 650 volts, 800 volts, 900 volts, 1000 volts, and 1200 volts. More particularly, a semiconductor device 100 according to aspects of the invention includes an ability to handle high voltage, high current, and higher temperatures, as the semiconductor device 100 is designed for high ruggedness, reliability, and stability in view of the BV of at least 650 volts. In other words, while the semiconductor device 100 can experience a sharp transition of voltage from source potential (i.e., ground or the source 102) to a highest voltage (the drain 103), the semiconductor device 100 according to aspects of the invention is designed with two or more termination units 101 to provide an improved electrical field distribution.

For instance, the first region 105 of the semiconductor device can be a single material, such as a single n-type material. Examples of the semiconductor device 100 include, but are not limited to, p-n junction diodes, Schottky diodes, and insulated gate bipolar transistor (IGBT). Examples of the n type materials include, but are not limited to silicon, silicon carbide and gallium nitride. In one or more embodiments, the first region 105 can include a silicon carbide (SiC) material. In this regard, the semiconductor device 100 is a SiC device that has superior performance for high voltage applications compared to Silicon (Si) devices of conventional technologies. Particularly, SiC provides the superior performance due to a bandgap (e.g., about 3.26 eV) that is almost three times larger than Si (e.g., about 1.12 eV).

The doping concentration of any layers of the first region 105, such as the electrical termination layer 135, can be determined, adjusted, and/or controlled by the design method (e.g., the method 300 of FIG. 3) herein. For instance, the electrical termination layer 135 can be doped based on a range. An example range of doping in the electrical termination layer 135 is 30% to 70% of the epitaxial layer 130. In this regard, the floating field rings 145 can be doped as p-type, the electrical termination layer 135 can be a lightly doped p-type layer, and the remaining portions of the first region 105 can be doped as n-type layers. Note that if the electrical termination layer 135 is too heavily doped, then the floating field rings 145 will not be able to acquire and distribute potential. Note also that the electrical termination layer 135 can reduce a dependence of the floating field rings 145 on a doping level of the epitaxial layer 130 and widen a manufacturing range of the process. Further, the doping can increase as the semiconductor device 100 progresses away from the second region 150 (e.g., the buffer layer 140 is more doped, such as 10% more, than the epitaxial layer 130). Generally, for each termination unit A-E, each channel via 165 connects each corresponding floating field ring 145 to each metal plate 170. Further, each connection via 175 connects each corresponding floating field plate 180. The channel vias 165, the connection vias 175, and the metal plates 170 can include metal. The floating field plates 180 can be heavily doped polysilicon, such as-type when the first region 105 is an n-type and vise-versa.

As shown in FIG. 2, a diagram of a termination unit 101 of FIG. 1 is depicted in detail, according to one or more embodiments. The termination unit 101 of FIG. 2 includes the floating field rings 145.1D-145.5D therein. The termination unit 101 of FIG. 2 includes a dielectric film 160D with the channel via 165D, the metal plate 170D, and the connection via 175, as well as the floating field plate 180D therein. According to one or more technical effects, advantages, and benefits, the termination unit 101 of FIG. 2 does not require that all floating field rings 145.1D-145.5D to be connected to the floating field plate 180, which significantly eases manufacturing processes and eliminates advanced lithography rules/equipment that make this design well suited for manufacturing. Thus, as shown, while one floating field ring 145.1D is coupled to the floating field plate 180D, the remaining floating field rings 145.2D-145.5D are not coupled.

The termination unit 101 of FIG. 2 may be considered as extending along the X1-X2 direction and each floating field ring 145 has a left or X1 side facing in the X1 direction, a right or X2 side facing in the opposite X2 direction, a bottom or Y1 side facing in the Y1 direction, and a top or Y2 side facing in the opposite X2 direction. By way of example, the termination unit 101 may extend from a right or X2 side 291 of the floating field ring 145.5C that is positioned to an immediate left (i.e., in the X1 direction) of the wider floating field ring 145.1D to an X2 side 292 of the floating field ring 145.5D that is to a left (i.e., in the X1 direction) of the next wider floating field ring 145.1E.

The termination unit 101 of FIG. 2 may also be considered as extending along the Y1-Y2 direction. By way of example, the termination unit 101 of FIG. 2 may extend from the lower or Y1 surface of the substrate layer 110 to the upper or Y2 surface of the dielectric film 160. By way of another example, the termination unit 101 of FIG. 2 may extend from the Y1 surface of the electrical termination layer 135 to the upper or Y2 surface of the dielectric film 160.

In connection with a termination unit 101 as in FIG. 1 and/or FIG. 2, a transition of voltage occurs from a highest voltage at the drain 102 (and a right or X2 side of the diagram) to the ground or source 101 (and a left or X1 side of the diagram). One or more technical effects, advantages, and/or benefits of the semiconductor device 100 including a termination unit according to aspects of the invention include, in response to this transition, to achieve a best possible electrical field distribution.

In this regard, in the Y1-Y2 direction of FIGS. 1 and 2 (i.e., along an axis from the substrate layer 110 to the surface of the second region 150), a certain distance to achieve the electrical field distribution is required. In the X1-X2 or lateral direction of FIGS. 1 and 2 (i.e., along an axis from a left side to a right side), the metal plates 170 form mechanical barriers on a surface of the region and are graded by having each section acquire a potential/voltage through the channel vias 165. That is, each acquired potential/voltage by each floating field ring 145 is transmitted from the channel via 165 to the metal plate 170, and further transmitted through the connection via 175 to the floating field plate 180 (i.e., as a short). Thus, each termination unit 101 (and more particularly the floating field plate 180 therein) does not have a fixed voltage. Rather, the potential/voltage or the voltage drop per termination unit A-E is adapted by design according to the locations and dimensions of the floating field rings 145 within the electrical termination layer 135.

More particularly, the voltage drop is controlled by an adaptive matrix of the plates 170 and 180 and the floating field rings 145. The term “adaptive” indicates that voltages are acquired as the voltages build. The term “matrix” indicates the arrangement of the plates 170 and 180 and the floating field rings 145. Thus, the adaptive matrix manages changes in the electric field distribution due to a gradual voltage drop distribution controlled by the gradual and controlled voltage drop of the floating field rings 145 because these components are uniquely positioned (e.g., by physical distances, locations, orientation, dimensions, etc.) and constructed (e.g., by physical size and dimensions, and what materials are positioned in contact or adjacent to each other) by the design method herein with respect to certain specifications and electric field distributions across the dielectric film 160 and the electrical termination layer 135.

According to one or more embodiments, the adaptive matrix thus includes particular arrangements of the plates 170 and 180 in combination with the floating field rings 145. The adaptive matrix illustrates a deep and fundamental difference between the semiconductor device 100 of FIG. 1 and conventional technologies. As noted herein, field plates of conventional technologies have fixed voltages (either a source voltage or a drain voltage that are defined by the device, and cannot be adapted). In contrast, the adaptive matrix of the plates 170 and 180 enable an “adaptive” voltage that is acquired as voltages build on the floating field rings 145 within the termination unites A-E and is distributed in an adaptive manner from in the termination through the vias 175 and 185.

According to one or more embodiments, the dielectric film 160 can be designated as inter-level-dielectrics (ILD) existing on top of the semiconductor material (i.e., the first region 105) and disposed between different embedded elements. Note that the insulation films deposited during manufacture of a device, as well as assembly and packaging of the device, typically uses a mold compound that can degrade an electric field distribution, which results in a lower BV. For instance, the electric field can shift or increase in value (e.g., an increase greater than 5E5 to 4E6 Volt/cm) across the device during normal use or when the device is put through burn-in and qualification procedures, which can create a problem for the functionality or degrade a rating of the device making it not able to maintain its electrical parameters). Yet, because the adaptive matrix of the plates 170 and 180 and the termination units A-E control the voltage drop, a change in the electric field distribution is prevented (due to the gradual and controlled voltage drop of the floating field rings).

FIG. 3 depicts a block diagram of a method 300 of producing an adaptive edge termination semiconductor device according to one or more embodiments. The method 300 is preferable employed to provide for a structure based on methodology that utilizes or otherwise relies upon target specifications for device design. Target specifications may be, for example, specifications based on end user, customer or designer requirements or specifications, proposed use of the semiconductor device, proposed functionality of the semiconductor device, end user, customer or designer preferences, or another source (i.e., a design or technical document or specification) to create an initial layout and refine the initial layout based on, for example, a BV design target.

By way of example, the method 300 provides for an iterative process of designing an semiconductor device having an adaptive edge termination, such as semiconductor device 100 of FIG. 1, by determining, setting, testing, and potentially redesigning and testing, unique or selected design parameters. These design parameters can include, by way of example, the quantity/number of the termination units, and the structure, dimensions, arrangement, composition, or elements thereof. By utilizing an iterative process, the method 300 may be used to design and refine terminations by, for example, coupling voltage drops in a termination to the metal and floating field plates 170 and 180, which take the voltage of the floating field rings 145 and distribute this voltage. It is appreciated that the devices that have a voltage rating above three hundred (300) volts are usually labelled “high” voltage devices. One or more technical effects, advantages, and benefits of the method 300 includes producing semiconductor devices capable of voltage distribution at least around 650 volts (e.g., up to and beyond 1200 volts or several thousands of volts).

The method 300 can be implemented via the use of software stored on at least one memory and executed by at least one processor. The at least one memory and the at least one processor can be embodied with other hardware, such as a bus or other communication mechanism, within a computing system or environment can include hardware. The at least one processor may be any type of general or specific purpose processor, including a central processing unit (CPU), application specific integrated circuit (ASIC), field programmable gate array (FPGA), graphics processing unit (GPU), controller, multi-core processing unit, three dimensional processor, quantum computing device, or any combination thereof. The at least one processor may also have multiple processing cores, and at least some of the cores may be configured to perform specific functions. Multi-parallel processing may also be configured. The at least one memory can be a non-transitory computer-readable media accessed by the at least one processor and may include volatile media, non-volatile media, or the like may be configured to store information, instructions, commands, or data to be executed or processed by the at least one processor. According to one or more embodiments, the software can include or be in communication with a technology computer aided design (TCAD) simulation software. Examples of TCAD simulation software include, but are not limited to Synopsys TCAD and Silvaco TCAD. According to one or more embodiments, the software can also leverage machine learning and/or artificial intelligence (using neural networks or the like).

The method 300 may begin at block 310, where a breakdown voltage (BV) design target (i.e., a defined or predetermined target for the semiconductor design) is determined and/or otherwise set. The breakdown voltage design target can be, for example, a BV for the semiconductor design (e.g., a SiC device design), plus or minus a determined percentage or range. The BV and the semiconductor design can be provided by a device design specification, for example, while accounting for the proposed use or desired functionality of the target device. The device design specification preferably provides details of desired characteristics of the target or proposed semiconductor device (e.g., the target specifications and parameters for device design), and may be stored in a media such as an electronic media. In this regard, the software can be utilized to receive and/or otherwise analyze the device design specification to assist in determining therefrom a semiconductor design and the BV. According to one or more embodiments, the software can receive one or more inputs (i.e., user inputs), to consider, determine, select, test or set various characteristics of the semiconductor design, such as the BV.

According to one or more embodiments, a BV may be selected as the breakdown voltage design target, or a value for the breakdown voltage design target is determined that is a percentage greater than a target BV. For instance, an initial input value may be selected that is 10% above that BV of the device design specification, which can then be a focal point any device simulation using the software. For example, if the device design specification indicates a BV of 650 volts, 800 volts, 900 volts, 1000 volts, 1200 volts, or 1800 volts, the selected breakdown voltage design target can be 715 volts, 880 volts, 900 volts, 1100 volts, 1320 volts, and 1980 volts, respectively. According to one or more embodiments, the breakdown voltage design target can be selected from a range, such as from 200 volts to 1800 volts. Note that these ranges and voltages are exemplary and not limiting.

The method 300 proceeds to one or more of blocks 320, 330, and 340, which can be executed in parallel or any sequence. Note that during any of the operations of blocks 320, 330, and 340, the software can leverage or otherwise utilize TCAD simulation software in view of the semiconductor design.

At block 320, an incremental voltage drop per termination unit is determined and/or otherwise set. The incremental voltage drop per termination unit is not representative of a specific value because the incremental voltage drop is an acquired or dynamically adapted voltage, resulting in the referenced adaptive termination units. The incremental voltage drop per termination unit is representative of an approximate target value that provide variance and flexibility to the design. For example, a selected incremental voltage drop of 200 volts represents a sub-range of +/−10 above or below 200 volts. In this regard, the incremental voltage drop can be a middle value detailed by a device design specification, or the software can receive inputs regarding the device design specification and determine therefrom the middle value. According to one or more embodiments, the software can receive one or more inputs (i.e., user inputs) that determine/select the incremental voltage drop. Thus, determining/setting the incremental voltage drop per termination unit implements an initial portion of the adaptive edge termination by design. The software may determine at what increments elements of the SiC device acquire or dynamically adapt voltages. This may be done, by way of example, by changing various target specifications and parameters of the design.

Note that considering an incremental voltage drop is completely inapplicable to conventional technologies, because the conventional dielectric layer elements provide fixed voltages according to material properties and through a capacitive coupling that govern the potential field distribution (e.g., there is no need for determining an incremental voltage drop since because these conventional dielectric layer elements are not adaptive). According to one or more embodiments, the incremental voltage drop can be selected from a range, such as a range from 50 volts to 300 volts, and can be an approximate target value from that range, such as 50 volts, 100 volts, 120 volts, 150 volts, 200 volts, and 300 volts. Note that the range and the approximate target value are exemplary and not limiting.

At block 330, a quantity/number of termination units is determined and/or otherwise set. By way of example, in accordance with the breakdown voltage design target and the determined incremental voltage drop, a minimum quantity/number of termination units are selected from a range. The range can be, for example, from four (4) units to eight (8) units. By way of example, if the selected breakdown voltage design target is 715 volts and the selected incremental voltage drop is 200 volts, then the software determines that the number of termination units required is four (4). With four (4) termination units and the 715 volts setting, the incremental voltage drop can be estimated at 178.75 (which is slighting under the +/−10 sub-range of 200 volts). Note that each termination unit can be designed differently base on a location of that termination unit. Also, note that on subsequent iterations, the software may select into 715 is 89.38 volts.

At block 340, a quantity/number of elements (e.g., the floating field rings 145) per termination unit is determined and/or otherwise set. For example, by executing the TCAD simulation software within one or more termination units, the software determines a number of elements along a range, such as from four (4) elements to six (6) elements, for that determination unit. Then, the software repeats this determination for the next termination unit until all termination units have a designated number of elements. Note that the range of elements can be “tighter” or “narrower” than the range of termination units. In this regard, the range of four (4) elements to six (6) elements is “tighter” or “narrower” than four (4) units termination to eight (8) units termination. This “tighter” or “narrower” arrangement of elements illustrates a tradeoff between forming smaller and tightly packed elements versus an ease of manufacturing a termination layout design.

At block 350, a structure of the semiconductor device is generated. The structure can be generated according to the breakdown voltage design target by utilizing one or more of the incremental voltage drop per termination unit, the number of termination units, and the quantity of elements per termination. For example, the software can generate the structure using the incremental voltage drop per termination unit, the number of the termination units, and/or the quantity of the elements per termination unit as inputs to TCAD simulation software. The structure can include, for example, parameters of the elements/components of the termination units, or components of the overall semiconductor device. In generating the structure, the software automatically determines sizes and dimensions of the floating field rings, and spacings therebetween, for each termination unit.

For example, referring to FIG. 2, using the device design specifications and software simulation as described: the floating field ring 145.1D of termination unit 101 may be determined to have a dimension A; the floating field ring 145.2D of termination unit 101 may be determined to have a dimension B; the floating field ring 145.3D of termination unit 101 may be determined to have a dimension C; the floating field ring 145.4D of termination unit 101 may be determined to have a dimension D; and the floating field ring 145.5D of termination unit 101 may be determined to have a dimension E. A, B, C, D and E may be dimensions such as height (in cross-section), width (in cross-section), and/or volume.

In this example, the dimension A>B, A>C, A>D, and A>E. Further, the dimensions B, C, D and E may be substantially equal, although it is appreciated that the dimensions may be the same or different as determined by the design method, preferably the method or methods as described herein.

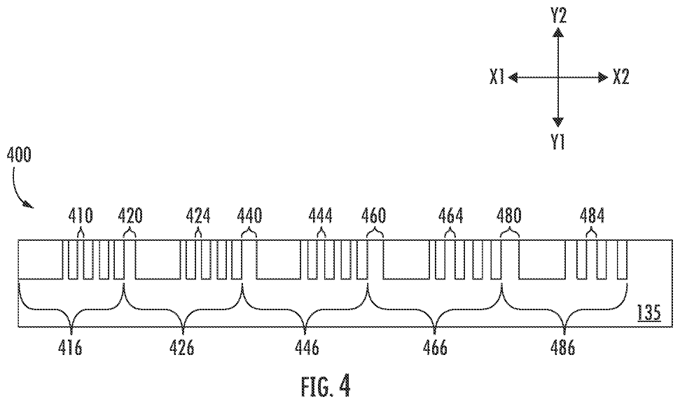

In this example, referring to FIG. 2, using the device design specifications and software simulation as described: a spacing S1 (or distance) is set between floating field ring 145.1D and 145.2D, a spacing S2 is set between floating field ring 145.2D and floating field ring 145.3D, a spacing S3 is set between floating field ring 145.3D and floating field ring 145.4D, and a spacing S4 is set between floating field ring 145.4D and 145.5D may be determined. Further, S1>S2, and S2, S3 and S4 may be substantially equal, although it is appreciated that the spacing (distances) may be the same or different. This spacing determinations can be further made across an entirety of a structure. Turning to FIG. 4, a diagram 400 of the electrical termination layer 135 is depicted according one or more embodiments.

The diagram 400 illustrates aspects of the electrical termination layer 135 that can be determined in the context of generating the one or more structures. The diagram 400 depicts a space 410 with respect to a floating field ring group 412, spaces 420 and 424 with respect to a floating field ring group 426, spaces 440, and 444 with respect to a floating field ring group 446, spaces 460 and 464 with respect to a floating field ring group 466, and spaces 480 and 484 with respect to a floating field ring group 486. Note that the floating field ring groups 416, 426, 446, 466, and 486 can respectively align with the termination unites A-E of FIGS. 1-2. The dimensions of each of these spaces 410, 420, 424, 440, 444, 460, 464, 480, and 484 can be set on along a range, i.e., from a sub-micron level (e.g., 0.0001 millimeters) to micron level (e.g., 0.009 millimeters). The dimensions of each of these spaces 410, 420, 424, 440, 444, 460, 464, 480, and 484 can vary when initially set with respect to each other or can be uniform.

According to one or more embodiments, in the context of generating the one or more structures, each floating field ring 145.1 that is coupled through a channel via 165 to a floating field plate 170 can have a wider width that any of the floating field rings 145.2-145.5 that are not coupled. Further, in the context of generating the one or more structures, the floating field rings 145.2-145.5 that are not coupled can maintain a same width. For example, the coupling of the floating field rings 145.1 to the metal plate 170 and floating field plate 180 combinations is determined by the software for an appropriate floating field ring 145.1 that drops a certain amount of voltage (e.g., that could range from 20 volts to 300 volts depending on a voltage level of the specification design). Again, not every floating field ring 145 is particularly coupled to a particular metal plate 170 and floating field plate 180 combination, but the groups (i.e., 492, 494, 495, 496, and 498) are associated with the particular metal plate 170 and floating field plate 180 combination.

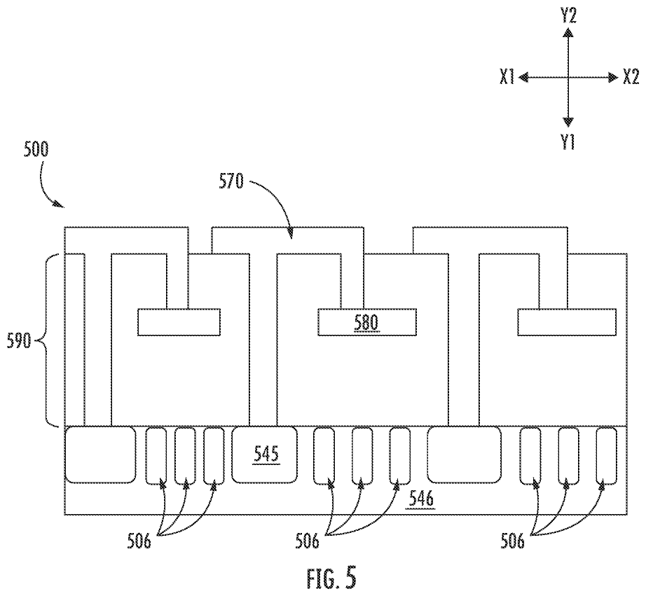

At decision block 360, the structure is evaluated. By way of example, FIG. 5 depicts a diagram of an structure 500 of the semiconductor device according to one or more embodiments. The structure 500 shows an example output of block 350 that a customer or designer may evaluate on a display or screen. The structure 500 shows provide of the adaptive edge termination including floating field rings 506 and 545 in a termination area 546, floating field plates 570 made of metal and floating field plates 580 made of polysilicon. The layer 590 can be an ILD (e.g., an inter level or layer dielectric material, typically some form of thermal and/or deposited oxide). It is appreciated that the floating field ring 545 connected to floating field plate 570 can be a p-well for an n channel MOSFET that could be the same as the p-body layer of the n channel MOSFET.

The decision block 360 includes sub-blocks 365 and 375, where a uniform distribution across the structure (an upper bound uniformity) is tested and confirmed, such as through use of the software described, and where energy of the structure is below a critical field for the elements therein is also tested and confirmed.

With respect to sub-block 365, the one or more structures are evaluated, such as by using the TCAD simulation, for electric field distribution to validate a uniform distribution. For example, during evaluations, it may be desired to minimize a number of floating field rings and/or termination units to simplify a final semiconductor device. Further, by way of example, the software can be set to seek to reduce the dimensions of each of the spaces 410, 420, 424, 440, 444, 460, 464, 480, and 484 from the initially set values, such as by individually changing (i.e., increasing or decreasing) these values. Further, evaluation by the software can include the software receiving one or more inputs, such as designated a specific foundry and considering the process design rules of that foundry to build the final semiconductor device. Thus, the software considers aspects of manufacturability.

With respect to sub-block 375, a critical field is evaluated for each element of the one or more structures using the TCAD simulation software. The critical field for each element may be a consideration of a material failure of the materials forming that element (i.e., the BV). For example, a tolerance on the epitaxial layer 130 determined by the supplier/foundry can be considered by the software in evaluating doping ranges for the electrical termination layer 135, such that a typical doping level range can be considered for the electrical termination layer 135. that is below a critical field.

In this manner, performance is optimized via the TCAD simulation software when designing the device. The structure start with equally spaces elements and simulations can return a breakdown voltage of structure (i.e., to make sure the structure is not over or under designed) and electric field distribution (i.e., to make sure the structure is not exceeding critical electrical field of the material (silicon has a particular rating) and that the field distribution is uniform). According to one or more embodiments, the electric field maximum value is less than 50% (10% to 40%) of the electrical field. The software (or customer/designer) can view, evaluate, and check that values are within an acceptable tolerance, such as 10% to 20%. If the things do not check, the method 300 can repeat (loop back) to one or more of the method steps to adjust any of the parameters that were selected and another simulation can be executed.

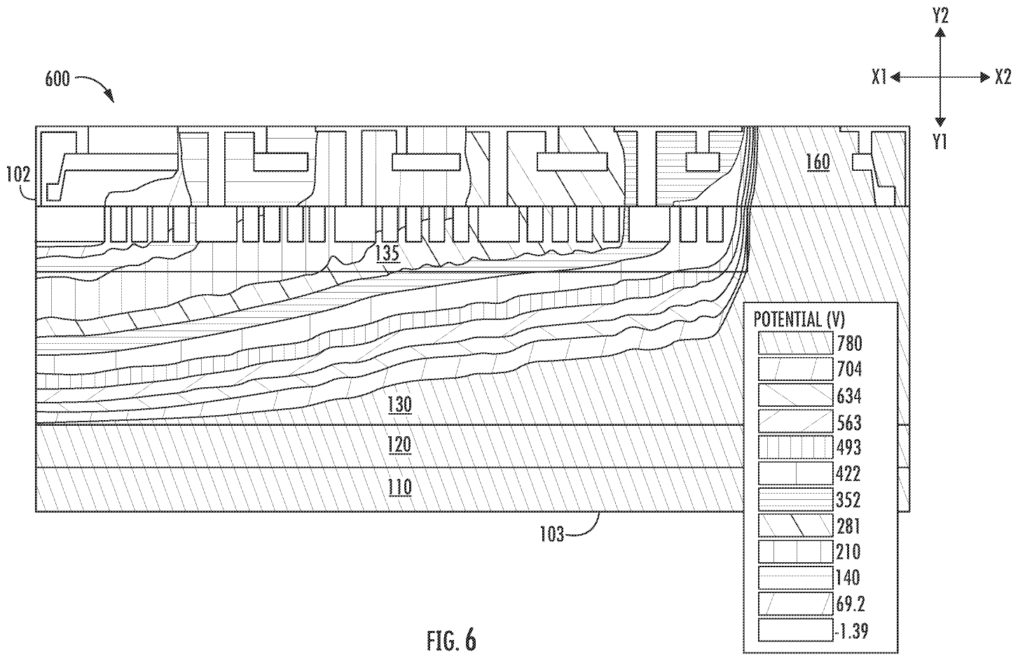

Turning now to FIG. 6, a diagram 600 of a gradual distribution of an electric field of an adaptive edge termination semiconductor device is depicted according one or more embodiments. Generally, in operation, as a voltage is ramped up, each floating field ring (e.g., 145) increases its potential until it reaches its full limit. This gradual increase illustrates the adaptive/dynamic nature of the embodiments herein. As shown in diagram 600, the gradual distribution of the electric field is from an edge at source 102 or ground potential on an X1 or left side of the termination to a drain 103 (which is at the peak voltage) on an X2 edge or right side of the termination. For example, a voltage begins at 0 across the adaptive edge termination semiconductor device 600. As the voltage increases, a first termination unit on a X1 or left most side will increase its potential until it reaches the 70 volt limit (shown as 69.2 volts). The remaining termination units will continue to increase. Since the voltages appear to stack after the fifth and final termination unit, further evaluation and adjustment is required by the software (or customer/designer). In some cases, another termination unit may be added with equal spacing and/or a number of elements changed per termination unit, as well as the spacing.

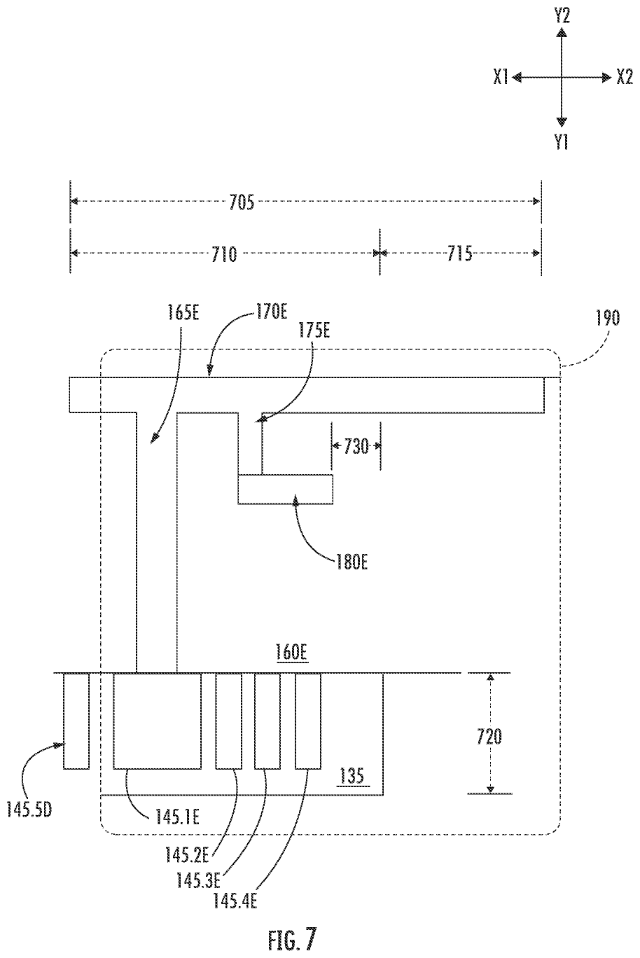

According to one or more embodiments, to address this stacking of the voltage, a dimension of a last metal plate and/or a last floating field plate (moving from the X1 to the X2 direction, thus, the one further to the right side of the Figures) can be set, determined or adjusted. Turning now to FIG. 7, a diagram of an adaptive edge termination semiconductor device according to one or more embodiments is shown. The metal plate 170E (i.e., the right side or last metal plate or a drain side metal plate) includes a length 705 that is an addition of a source side length 710 and a drain side length 715. The source side and drain side lengths 710 and 715 are measured from a drain side or X2 surface of the epitaxial layer 135. In this regard, a drain side or X2 surface of the metal plate 170E extends outside of or beyond the drain side or X2 surface of the epitaxial layer 135. According to one or more embodiments, the drain side length 715 is equal to or greater than a junction depth 720 of the epitaxial layer 135. For example, the drain side length 715 can be a 2:1 size ratio to the junction depth 720. Further, the floating field plate 180E (i.e., the last floating field plate a drain side floating field plate) can have a drain side or X2 surface inside or within a drain side surface of the epitaxial layer 135, as indicated by the X1-X2 distance 730. Thus, the extension of the metal plate 170E addresses the stacking of the voltage by spreading the voltage across a greater surface distance (i.e., the drain side length 715 that is equal to or greater than the junction depth 720).

At block 390, a final termination layout design for the breakdown voltage design target is determined. The final termination layout design, with an electrical field distribution, reduces peak electric field in the dielectric layer and prevents instability due to charges that could exist in the dielectric layer from adversely creating a high electric field that would result in lowering of the BV. For example, in SiC material, high electric fields would range from 5E5 to 4E6 Volt/cm, a peak electric field region designates a maximum value of the electric field in the device and it is fairly limited in area, as the electric field is not uniform across the device. Thus, the semiconductor device 100 has a “rugged and stable” BV, i.e., a constant BV during a lifetime of the semiconductor device 100 under different operating conditions and that does not vary during stress and qualification procedures needed to qualify the semiconductor device.

Examples of different semiconductor implementations have been described with reference to the accompanying drawings. These examples are not mutually exclusive, and features found in one example can be combined with features found in one or more other examples to achieve additional implementations. Accordingly, it will be understood that the examples shown in the accompanying drawings are provided for illustrative purposes only and they are not intended to limit the disclosure in any way.

One of ordinary skill in the art would understand that additional method steps can be included, such as additional cutting, bending, stacking, layering, etc.

It will be appreciated that the foregoing is presented by way of illustration only and not by way of any limitation. It is contemplated that various alternatives and modifications may be made to the described embodiments without departing from the spirit and scope of the invention. Having thus described the present invention in detail, it is to be appreciated and will be apparent to those skilled in the art that many physical changes, only a few of which are exemplified in the detailed description of the invention, could be made without altering the inventive concepts and principles embodied therein. It is also to be appreciated that numerous embodiments incorporating only part of the preferred embodiment are possible which do not alter, with respect to those parts, the inventive concepts and principles embodied therein. The present embodiment and optional configurations are therefore to be considered in all respects as exemplary and/or illustrative and not restrictive, the scope of the invention being indicated by the appended claims rather than by the foregoing description, and all alternate embodiments and changes to this embodiment which come within the meaning and range of equivalency of said claims are therefore to be embraced therein.

What is claimed is:

1. A semiconductor device comprising:
two or more termination units, wherein each of the two or more termination units comprise:
a via channel;
a connection via;
a plurality of floating field rings comprising a first floating field ring having a first width and a second floating field ring having a second width, the first width being different than the second width;
a metal plate coupled to the first floating field ring through the via channel; and
a floating field plate coupled to the metal plate through the connection via,
wherein the two or more termination units provide an electric field distribution configured to dissipate a voltage passing from a drain of the semiconductor device to a source of the semiconductor device.

2. The semiconductor device of claim 1, wherein each of the two or more termination units extends from a first region of the semiconductor device into a second region of the semiconductor device.

3. The semiconductor device of claim 2, wherein the first region comprises at least one dielectric film, the metal plates of the two or more termination units, and the floating field plates of the two or more termination units.

4. The semiconductor device of claim 2, wherein the plurality of floating field rings of each of the two or more termination units are resident in an electrical termination layer of the second region.

5. The semiconductor device of claim 1, wherein a width of each of the two or more termination units extends from an outer wall of the first floating field ring to an outer wall of the second floating field ring.

6. The semiconductor device of claim 1, wherein the first width is greater than the second width.

7. The semiconductor device of claim 1, wherein each of the two or more termination units is configured to contribute to the electric field distribution in accordance with a voltage drop across the termination units.

8. The semiconductor device of claim 1, wherein the floating field plate of each of the two or more termination units is associated with at least one of the plurality of floating field rings of the same termination unit.

9. The semiconductor device of claim 1, wherein at least one of the plurality of floating field rings of each of the two or more termination units is not associated with the corresponding floating field plate of the same termination unit.

10. The semiconductor device of claim 1, wherein each of the plurality of floating field plates comprise polysilicon.

11. The semiconductor device of claim 1, wherein the semiconductor device comprises a metal-oxide semiconductor field-effect transistor.

12. The semiconductor device of claim 1, wherein the plurality of floating field rings are provided within an implanted layer of a same conductivity type as the plurality of floating field rings, and
wherein the implanted layer comprises a doping concentration that is lower than a doping concentration of the plurality of floating field rings.

13. The semiconductor device of claim 12, wherein the doping concentration of the implanted layer is within a range of about 30% to about 70% higher than a doping concentration of an epitaxial layer of the semiconductor device.

14. The semiconductor device of claim 1, wherein a drain side surface of a drain side metal plate extends beyond a drain side surface of an epitaxial layer of the semiconductor device.

15. The semiconductor device of claim 1, wherein a drain side length of a drain side metal plate is equal to or greater than a junction depth of an epitaxial layer of the semiconductor device.

16. A method for forming a semiconductor device, the method comprising:
determining a breakdown voltage design target based on a predetermined breakdown voltage for the semiconductor device;
generating a structure for the semiconductor device comprising at least two termination units according to the breakdown voltage design target utilizing one or more of an incremental voltage drop per termination unit, a number of termination units, and a quantity of elements per each termination unit; and
evaluating whether the structure provides for a uniform distribution or an energy below a critical field; and
determining a final termination layout design for the semiconductor device.

17. The method of claim 16, wherein the number of termination units is selected from a range of four units to eight units and quantity of elements per termination is selected from a range of four units to six units.

18. The method of claim 16, further comprising the step of utilizing software to perform a simulation to automatically determine dimensions of elements and spacings between elements for each termination unit of the structure when generating the structure.

19. The method of claim 16, wherein the method iteratively repeats one or more steps in order to optimize the structure into the final termination layout design by adjusting the one or more of the incremental voltage drop per termination unit, the number of termination units, and the quantity of elements per termination unit.

20. A termination unit of semiconductor device comprising:
a via channel;
a connection via;
a plurality of floating field rings;
a metal plate coupled to the first floating field ring through the via channel; and
a floating field plate coupled to the metal plate through the connection via,
wherein a drain side surface of the metal plate extends beyond a drain side surface of an epitaxial layer of the semiconductor device and wherein a drain side length of the metal plate is equal to or greater than a junction depth of the epitaxial layer.
